(19) United States
(12) Patent Application Publication
(10) Pub. No.: US 2025/0063708 A1
(43) Pub. Date: Feb. 20, 2025

(54) Operating an Electronics Production Line

(71) Applicant: Siemens Aktiengesellschaft, München (DE)

(72) Inventors: Bernd Müller, Falkenberg (DE); Ulrich Wittreich, Velten (DE); Kay Jarchoff, Berlin (DE); Michael Hanisch, Hohen Neuendorf (DE); Michael Erdmann, Borkheide (DE); Carsten Borwieck, Berlin (DE)

(73) Assignee: Siemens Aktiengesellschaft, München (DE)

(21) Appl. No.: 18/722,375

(22) PCT Filed: Nov. 16, 2022
(86) PCT No.: PCT/EP2022/082059

§ 371 Date: Jun. 20, 2024

(30) Foreign Application Priority Data
Dec. 22, 2021 (EP) 21216754.8

(51) Int. Cl. H05K 13/08; H05K 13/04

(52) U.S. Cl. CPC H05K 13/083; H05K 13/0417; H05K 13/0465

(57) ABSTRACT

Various embodiments of the teachings herein include a method for operating an electronics production line for producing electronic assemblies. The electronics production line comprises a device to apply joining material onto component carriers, an assembly device to place electronic components onto the component carriers, a joining device to join the electronic components to the component carriers, and a transport to transport the component carriers through the production line. An example method includes: transporting a process parameter acquisition system through the electronics production line on the transport; measuring actual process parameter values with the process parameter acquisition system; providing setpoint process parameter values; determining any deviations between actual and setpoint process parameter values; and providing a dataset including the deviations.

### CROSS-REFERENCE TO RELATED APPLICATIONS

This application is a U.S. National Stage Application of International Application No. PCT/EP2022/082059 filed Nov. 16, 2022, which designates the United States of America, and claims priority to EP application Ser. No. 21/216,754.8 filed Dec. 22, 2021, the contents of which are hereby incorporated by reference in their entirety.

### TECHNICAL FIELD

The present disclosure relates to production of electronics. Various embodiments of the teachings herein include methods and/or systems for operating an electronics production line, an electronics production line, and process parameter acquisition systems.

### BACKGROUND

Electronics production lines are used in production facilities for industrial electronics, power electronics and microelectronics, for example. Typically, electronics production lines have devices for performing individual production steps. These devices usually have sensors that are designed to acquire the respective device-specific parameter values, e.g. temperatures and residual oxygen content in a reflow oven. Pick-and-place machines, template printers and reflow ovens can each acquire parameter values within the individual device. In order that continuous compliance with the required process conditions can be guaranteed, it is advantageous, in addition to closed-loop control and/or open-loop control within the individual devices, to regularly align the actual values that in reality occur at product level with the setpoint process parameters for the respective product.

The proof of compliance with the required process conditions for a defined product, e.g. an electronic assembly, is extremely important with regard to a guarantee of quality, particularly in the case of mass production and in live operation.

### SUMMARY

The teachings of the present disclosure may be used to ensure compliance with process specifications at product level. For example, some embodiments of the teachings herein include a method for operating an electronics production line (200) for producing electronic assemblies (100), wherein the electronics production line (200) comprises a device (20) for applying joining material onto one or more component carriers (PCB), an assembly device (30) for placing electronic components onto the component carriers (PCB), a joining device (40) for joining the electronic components to the component carriers (PCB), and a transport system (250) which is designed to transport the component carriers (PCB) through the devices (20, 30, 40), and wherein a process parameter acquisition system (AIO) passes through the electronics production line (200) on the transport system (250), the process parameter acquisition system (AIO) provides actual process parameter values (ACT1, ACT2), setpoint process parameter values (SET) are provided, deviations (DEV) between actual and setpoint process parameter values (SET, ACT1, ACT2) are determined, and a dataset (D) that comprises at least the deviations (DEV) is output.

In some embodiments, the actual parameter values (ACT1, ACT2) also comprise at least one measured value that is provided by one of the devices (20, 30,40).

In some embodiments, the method further comprises: outputting a warning report (ERR) if the deviations (DEV) exceed a respective threshold value and/or outputting a conformity dataset (QD) if the deviations (DEV) remain below a respective threshold value.

In some embodiments, the actual process parameter values (ACT1, ACT2) comprise at least one residual oxygen concentration and/or temperature that is acquired by means of the process parameter acquisition system (AIO).

In some embodiments, the actual process parameter values (ACT1, ACT2) and/or the deviations (DEV) are acquired in each case for a definable number of assemblies (100) before and/or after the production thereof.

In some embodiments, the method further comprises outputting a calibration dataset if the deviations (DEV) exceed a respective threshold value.

In some embodiments, each assembly (100) produced is assigned a conformity dataset (QD) which contains the deviations.

In some embodiments, the electronics production line (200) and/or a supervisory production control prompts a process parameter acquisition system (AIO) following a definable number of assemblies (100) produced.

As another example, some embodiments include a method for automatically calibrating an electronics production line (200), comprising: operating an electronics production line (200) with a method as claimed in one of the preceding claims, and setting an offset in at least one of the devices (20, 30, 40) on the basis of the deviations (DEV).

In some embodiments, second deviations are received from a second electronics production line which is embodied for the production of the same product and is operated in accordance with one of the preceding claims, and the setting of an offset in at least one of the devices (20, 30, 40) takes place using the second deviations (DEV).

As another example, some embodiments include an electronics production line (200) for performing a method as claimed in one of the preceding claims, having a device (20) for applying joining material onto component carriers (PCB), an assembly device (30) for placing electronic components onto the component carriers (PCB), a joining device (40) for joining the electronic components to the component carriers (PCB), a transport system (250) that is designed to transport the component carriers (PCB) through the devices (20, 30, 40), a communication interface (COM1) that is designed to communicate with the process parameter acquisition system (AIO), and an evaluation device (210) that is designed to determine deviations (DEV) between actual and setpoint process parameter values (SET, ACT1, ACT2).

### BRIEF DESCRIPTION OF THE DRAWINGS

The teachings of the present disclosure are described and explained in greater detail below with reference to the exemplary embodiments illustrated in the figures, in which:

FIG. 1 schematically shows an example electronics production line incorporating teachings of the present disclosure;

FIG. 2 shows a schematic cross section through a transport system teachings of the incorporating present disclosure;

FIG. 3 schematically shows an example process parameter acquisition system incorporating teachings of the present disclosure on a transport system;

FIG. 4 schematically shows an example joining device incorporating teachings of the present disclosure; and

FIG. 5 shows a schematic illustration of the data flow within the example electronics production line.

### DETAILED DESCRIPTION

In this example, an electronics production line has at least one device for applying joining material onto one or more component carriers, an assembly device for placing electronic components onto the component carriers, a joining device for joining the electronic components to the component carriers, and a transport system that is designed to transport the component carriers through the devices. The method comprises:
passing a process parameter acquisition system through the transport system,
providing actual process parameter values by means of the process parameter acquisition system,
providing setpoint process parameter values,
determining differences, i.e. deviations, between actual and setpoint process parameter values, and
outputting a dataset that comprises at least the deviations.

Actual process parameter values are the real parameter values that are acquired in or in the environment of the electronics production line by means of e.g. sensors or counters. They include inter alia temperatures, residual oxygen concentrations, accelerations, clocking of the line, relevant forces and further parameters.

Component carriers include any printed circuit boards that can be transported through the production line by means of a transport system, e.g. PCBs, DCBs, etc. The components are SMD or THD components. So-called bare dies can be processed as components.

The setpoint process parameter values are the parameter values that are to act on the electronic assemblies or on the component carriers during the production of the electronic assemblies. Compliance with the setpoint process parameter values is ensured by means of an open-loop and/or closed-loop control system in every device. The determination of deviations between actual and setpoint process parameter values therefore means checking whether the devices themselves are still able to comply with the setpoint process parameter values. A closed-loop or open-loop control system within a device would not be able to identify such a deviation, since it has only its own measured values available. It may also be the case that a closed-loop control system in the device is itself too tolerant of drifting values. Finally, the deviations can be documented in the inventive dataset and used for other purposes.

In some embodiments, the actual parameter values comprise at least one measured value that is provided by one of the devices. The actual parameter values therefore comprise not only actual values in the region around the transport system, but also parameter values that are provided by the sensors of the devices outside the region. This allows the creation of a more complete dataset, more accurate determination of the deviations and, most importantly, the context is provided for the measured values in the region.

In some embodiments, the method comprises outputting a warning report if the deviations exceed a respective threshold value and/or outputting a conformity dataset if the deviations remain below a respective threshold value. If the deviations exceed a threshold value, this does not necessarily have to result in an immediate stoppage of the production line, and a corresponding servicing requirement or a readjustment of certain parameters may be indicated by the proposed method instead.

A conformity dataset confirms that the process parameter values corresponded to the maximum deviations required during the production of the assemblies. Such a conformity dataset can be associated with a certain number of assembly serial numbers and output in an optionally cryptographic manner as a certificate for the defined number of serial numbers.

In some embodiments, the actual process parameter values comprise at least one residual oxygen concentration in the region and/or a temperature in the region. In this case, the actual process parameter values can be acquired at a plurality of points in the region along the transport system, thereby producing a history of parameter values. It is however sufficient in principle to acquire a residual oxygen concentration and a temperature at particularly important points in the region. It has been found that the residual oxygen concentration and the temperature at component carrier level represent a very good indicator of a quality of the production. If deviations from the setpoint values occur in the region, these deviations can indicate a need to service the installation, a need to calibrate specific sensors in the installation, or other types of fault in the installation.

Acquiring actual process parameter values using such a process parameter acquisition system takes advantage of the relevance of the acquired measured values to the real process conditions and how they act on the electronic assemblies or the component carriers.

In some embodiments, the actual process parameter values and/or the deviations are acquired in each case for a definable number of assemblies before and/or after the production thereof. For the number of assemblies that are to be produced under identical conditions, the actual process parameters can be acquired regularly in each case in order to ensure that the same conditions also applied in relation to all assemblies produced. For example, a set of actual process parameters can be acquired and documented every 10, 20, 50 or every 100 assemblies.

In some embodiments, the method comprises of outputting a calibration dataset if the deviations exceed a respective threshold value. If measured values from the sensors of the devices include constant values or values which do not change to the same extent as the measured values that are acquired in the region, it must be assumed that a calibration or an offset correction of the sensor system is required in the devices. Such a calibration dataset can serve as an initial indication. If a calibrated process parameter acquisition system is used, at least an initial calibration can be performed automatically by the electronics production line itself by means of automatically setting corresponding offset values. This can lengthen the time period between laboratory-based calibrations requiring removal of the sensor, and consequently allows a production which complies with constant quality standards over an extended time. In some embodiments, the calibration data can comprise at least a residual oxygen concentration and a temperature, both of which were acquired in the region.

In some embodiments, each of the assemblies produced is assigned a conformity dataset which contains the deviations in the region. It is thereby possible to see, for each assembly, whether there were deviations at assembly level and how great these were. For example, this data can be used to make a selection of particularly high-quality assemblies for applications under particularly high load.

In some embodiments, the electronics production line and/or a supervisory production control prompts a process parameter acquisition system following a definable number of assemblies produced. Acquisition of the relevant parameters can take place and the inventive dataset thus be created in a completely automatic manner. In some embodiments, the process parameter acquisition system can independently register itself with the electronics production line in order to perform a check. The electronics production line can then maintain all process parameters but e.g. perform a test placement without components in order to measure forces. It has been found advantageous for the acquisition entity to travel through the electronics production line directly after or between a definable number of assemblies, since the thermal quantities in the line and the process forces and accelerations which occur at that point are the most realistic.

Some embodiments include a method for automatically calibrating an electronics production line. In this case, the electronics production line is operated in accordance with a method as per one of the preceding embodiments. An offset can also be set in order to perform a calibration in at least one of the devices on the basis of the deviations in the dataset.

Some embodiments include an electronics production line which is designed to perform a method in accordance with one of the preceding embodiments. In this case, the electronics production line has devices for applying joining material onto component carriers, for placing electronic components onto the component carriers and for joining the electronic components to the component carriers. A transport system is designed and provided to transport the component carriers through the devices in this case. The electronics production line further comprises an evaluation device which is designed to determine deviations between actual and setpoint process parameter values. In this case, the evaluation device can further comprise a communication interface which is designed to communicate with a process parameter acquisition system that is designed to pass through the electronics production line on the transport system. In this case, the communication interface can also convey a notification of the acquisition system to the individual devices that e.g. a pick-and-place machine is to suspend placement or that empty placement without components is required in order to perform a force measurement.

It is possible to receive second deviations from a second electronics production line which is embodied and is likewise operated for the production of the same product, and to set an offset in at least one of the devices using the second deviations.

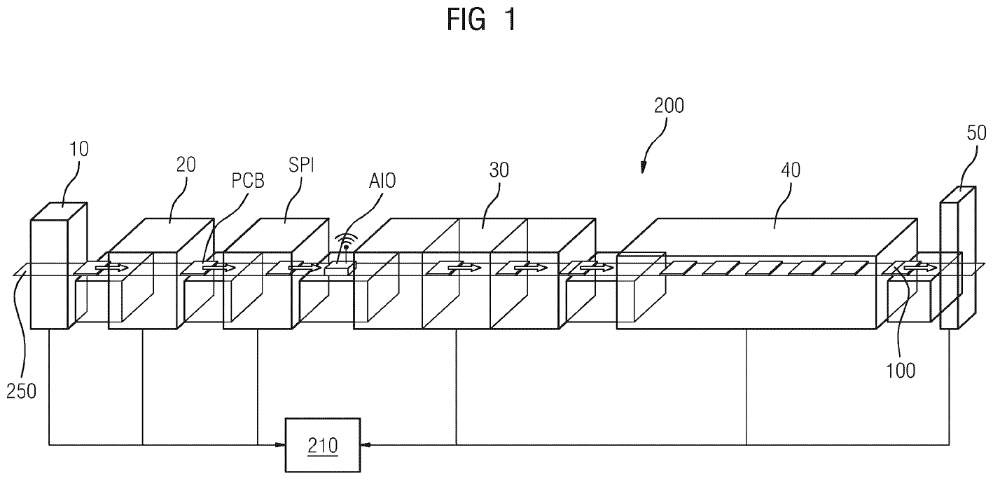

FIG. 1 schematically shows an example electronics production line 200 incorporating teachings of the present disclosure with its individual devices 10, . . . , 50, these being interconnected via a transport system 250. A supply device 10 supplies component carriers PCB, which are then transported via the transport system 250 into a device 20 for applying joining material. Next is shown an inspection device SPI, which in the present case can be a solder-paste inspection device and provides quality data in respect of a joining material coating. Next is shown an assembly device 30, which places electronic components onto the component carriers PCB that have been provided with joining material. A joining device 40, e.g. a reflow oven, then joins the electronic components to the component carriers PCB by means of fusing or sintering a joining material. The joining operation also results in the electronic assemblies 100, which can then be collected in a collecting device 50. Also shown is a process parameter acquisition system AIO which is designed to travel through the electronics production line 200 on the transport system 250. The acquisition system AIO is therefore embodied in such a way that it can be transported by means of the transport system 250 in the same way as the component carriers PCB. In this case, the electronics production line 200 can be supplemented with devices 10, . . . , 50 that are required for the assemblies 100. For example, a plurality of pick-and-place machines 30 or a plurality of inspection devices can be provided in a line 200.

An evaluation device 210 has a communication connection to the devices 10, . . . , 50. In this way, a direct communication connection to the individual devices 10, . . . , 50 is provided in the present case. It is also possible for one individual device 10, . . . , 50 to collect the data of all the others, or to provide a communication connection via respective other devices 10, . . . , 50, such that every individual device 10, . . . , 50 need not be connected.

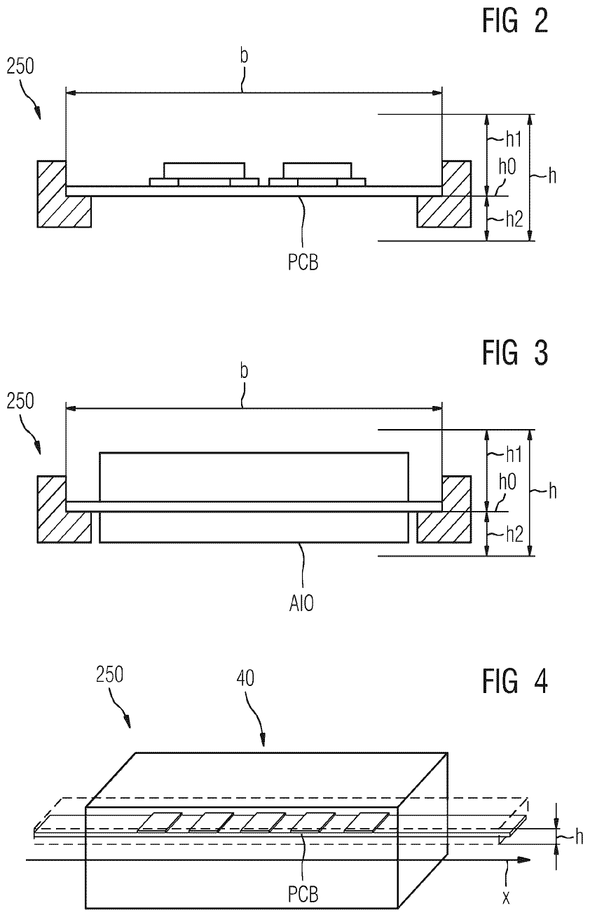

FIG. 2 shows a schematic cross section through the transport system 250 shown in FIG. 1. In electronics production lines, provision is often made for a chain-based transport system which transports the component carriers PCB through the electronics production line 200 using e.g. clamping means. In this case, the transport system 250 can be adjusted across the width b such that the different component carriers PCB can be reliably transported. Also shown is a transport plane h0, which is derived from the support of the transport system 250 on which the component carriers PCB lie. A region h around the transport plane is also defined as a region h1 above the transport plane h0 and a region h2 below the transport plane h0. Maximum values of 35 mm for the region h1 above and 25mm for the region h2 below the transport system 250 have been found to be advantageous, since these are observed in common electronics production lines and common loaded component carriers. It can therefore be assumed that if a measured value is acquired in the region h, said value largely represents the conditions and/or process parameters that in reality act on a component carrier PCB. In this case, the width of the region h is limited to the maximum transport width b that can be provided by the transport system 250. Measured values are best obtained within the region h at those locations where on average most components pass. For example, this may be centrally relative to the width b and 1 mm to 5 mm above the transport plane h0. It is equally possible for a plurality of measuring points to be distributed across the width b.

FIG. 3 schematically shows a process parameter acquisition system AIO incorporating teachings of the present disclosure and transported on the transport system 250. The region h and the width b are indicated in a similar way to FIG. 2. It can also be seen that the process parameter acquisition system AIO does not have to occupy the whole region h. When the process parameter acquisition system AIO travels through the region h, a process parameter value profile can be generated by means of acquiring values at a plurality of points or (quasi) continuously, e.g. at a suitable sampling frequency.

FIG. 4 schematically shows an example joining device 40 incorporating teachings of the present disclosure with a section of the transport system 250 and a graphical illustration of the manner in which the region h extends along the direction of movement x through the joining device 40. The region h thus forms a virtual tunnel around the transport system, in which the process parameter values must correspond to the setpoint values. The region h in this case is always situated within the respective device 10, . . . , 50 except in sections of the transport system 250 which are arranged between, before or after the respective devices.

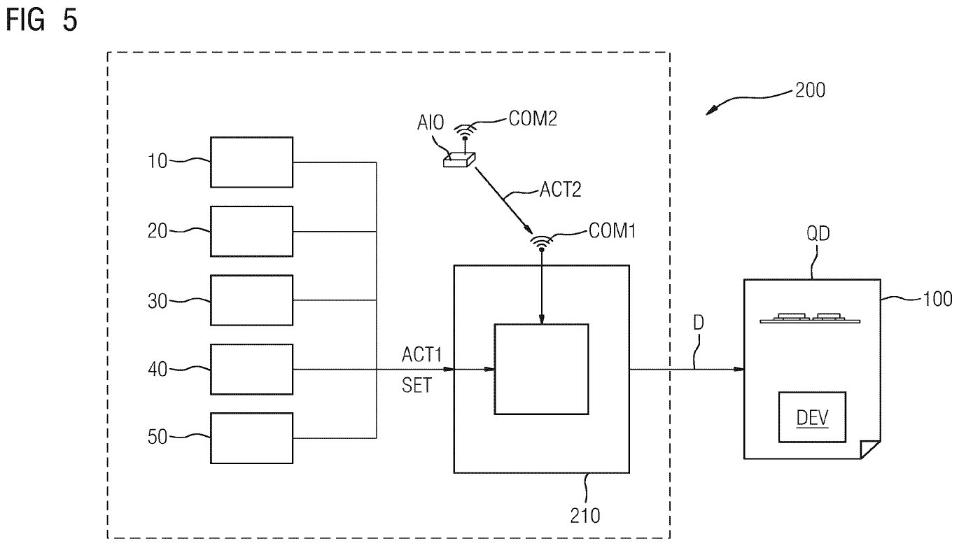

FIG. 5 shows a schematic illustration of an example data flow within an electronics production line 200 incorporating teachings of the present disclosure. The evaluation device 210 is a central element in this case. The devices 10, . . . , 50 provide first actual process parameter values ACT1. In this case, the first actual process parameter values ACT1 are parameter values that are acquired and output directly by the devices 10, . . . , 50 (e.g. temperatures outside the region h but within the device 10, . . . , 50, forces, accelerations, cycle times, etc.).

The evaluation device 210 further has a first communication interface COM1 which is designed to communicate with a second communication interface COM2 of a process parameter acquisition system AIO. In this case, the process parameter acquisition system AIO is designed to pass through the electronics production line 200 on a transport system 250 (not shown here). In this case, the communication interfaces COM1, COM2 can be so designed as to allow communication during the passage. In some embodiments, the process parameter acquisition system AIO can also comprise an internal memory for the acquired data, which can then be transmitted to the evaluation device 210 immediately after passing through, in order to allow an association with the live production process.

In this case, the process parameter acquisition system AIO supplies the second actual process parameter values ACT2, which are acquired in the region h and therefore reflect the parameter values which in reality act on the component carriers PCB. In this case, the evaluation device 210 can ascertain a deviation DEV on the basis of the first and the second actual process parameter values ACT1, ACT2 and the setpoint process parameter values SET shown here for the respective devices 10, . . . , 50. This deviation DEV, a selection of or all setpoint process parameters SET, and a selection of or all actual process parameters ACT1, ACT2 can then be saved in a dataset D. The deviation DEV can be a difference in this case but it is equally possible to perform corresponding mathematical analyses which show the tendencies or trends in histories of values.

The process parameter acquisition system AIO can pass through the electronics production line 200 automatically during live production (e.g. per batch or following a defined number of assemblies). To this end, it can register itself with the installation or be registered and prompted from a central evaluation device 210, then pass through the line 200 and perform corresponding measurements for process parameter values ACT2 in the region h. Further assemblies can be produced immediately following the process parameter acquisition system AIO.

The dataset D can be converted into a conformity dataset QD which confirms the conformity of the process parameter values for a defined number of electronic assemblies 100. If the deviations no longer correspond to the specifications, e.g. a certain threshold is exceeded, a warning report which documents the deviations can be output. Corresponding steps can be initiated accordingly. The steps can be based on fault finding in this case, e.g. a leakage or a defect in a sensor or heating element. The deviations can be observed over an extended time period, e.g. by comparing a plurality of conformity datasets. If a drift of the deviations DEV is established, an offset value for calibrating sensors of the devices 10, . . . , 50 can be set. If this correction is not successful, a calibration of the sensors in the laboratory of the devices 10, . . . , 50 may be indicated.

In summary, the present disclosure describes methods for operating an electronics production line 200 for producing electronic assemblies 100. An example electronics production line 200 comprises:
a device 20 for applying joining material onto one or more component carriers PCB;
an assembly device 30 for placing electronic components onto the component carriers PCB;
a joining device 40 for joining the electronic components to the component carriers PCB; and
a transport system 250 which is designed to transport the component carriers PCB through the devices 20, 30, 40.

In order to ensure compliance with process specifications at product level, an example method comprises:
providing actual process parameter values ACT1, ACT2 comprising at least one parameter value that is acquired in a limited region h around the transport system 250;
providing setpoint process parameter values SET;
determining deviations DEV between actual and setpoint process parameter values SET, ACT1, ACT2; and
outputting a dataset D that comprises at least the deviations DEV.

### Reference Signs

100 Electronic assembly
PCB Component carrier
200 Electronics production line
210 Evaluation device
10 Supply device
20 Device for applying joining material
30 Assembly device
40 Joining device
50 Collecting device
250 Transport system
h0 Transport plane
h Region
h1, h2 Region above/below the transport plane
SPI Inspection device
SET Setpoint process parameter values
ACT1, ACT2 Actual process parameter values
DEV Deviations
D Dataset
QD Conformity data

What is claimed is:

1. A method for operating an electronics production line for producing electronic assemblies, wherein the electronics production line comprises
a device to apply joining material onto component carriers,
an assembly device to place electronic components onto the component carriers,
a joining device to join the electronic components to the component carriers, and
a transport to transport the component carriers through the production line, the method comprising:
transporting a process parameter acquisition system through the electronics production line on the transport;
measuring actual process parameter values with the process parameter acquisition system;
providing setpoint process parameter values;
determining any deviations between actual and setpoint process parameter values;
providing a dataset including the deviations.

2. The method as claimed in claim 1, wherein the actual parameter values comprise a measured value provided th production line.

3. The method as claimed in claim 1, further comprising:
generating a warning report if the deviations exceed a respective threshold value; and/or
generating a conformity dataset if the deviations remain below a respective threshold value.

4. The method as claimed in claim 1, wherein the actual process parameter values comprise residual oxygen concentration and/or temperature acquired by the process parameter acquisition system.

5. The method as claimed in claim 1, wherein the actual process parameter values and/or the deviations are acquired in each case for a definable number of assemblies before and/or after the production thereof.

6. The method as claimed in claim 1, further comprising generating
a calibration dataset if the deviations exceed a respective threshold value.

7. The method as claimed in claim 1, further comprising assigning a conformity dataset for each assembly produced, the conformity dataset including the deviations.

8. The method as claimed in claim 1, wherein the electronics production line prompts the process parameter acquisition system following a definable number of assemblies produced.

9. A method for automatically calibrating an electronics production line, the method comprising:
operating an electronics production line;
transporting process parameter acquisition system through electronics production line on a transport;
measuring actual process parameter values with the process parameter acquisition system;
providing setpoint process parameter values;
determining any deviations between actual and setpoint process parameter values;
providing a dataset including the deviations; and setting an offset in at least one part of the electronics production line based at least in part on the deviations.

10. The method as claimed in claim 9, further comprising:
receiving second deviations from a second electronics production line for the production of the same product; and
setting of an offset in the production line depends at least in part on the second deviations.

11. An electronics production line comprising:
a device to apply joining material onto component carriers;
an assembly device to place electronic components onto the component carriers; a joining device to join the electronic components to the component carriers;
a transport to transport the component carriers through the devices production line;
a communication interface to communicate with a process parameter acquisition system; and
an evaluation device designed to determine deviations between actual and setpoint process parameter values.
